(19) United States
(12) Patent Application Publication
(10) Pub. No.: US 2025/0063666 A1
(43) Pub. Date: Feb. 20, 2025

(54) PRINTED CIRCUIT BOARD

(71) Applicant: SAMSUNG ELECTRO-MECHANICS CO., LTD., Suwon-si (KR)

(72) Inventor: Dae Jung BYUN, Suwon-si (KR)

(73) Assignee: SAMSUNG ELECTRO-MECHANICS CO., LTD., Suwon-si (KR)

(21) Appl. No.: 18/627,184

(22) Filed: Apr. 4, 2024

(30) Foreign Application Priority Data
Aug. 14, 2023 (KR) 10-2023-0106257

(51) Int. Cl. H05K 1/18; H05K 1/02; H05K 1/11

(52) U.S. Cl. CPC H05K 1/185; H05K 1/0298; H05K 1/115; H05K 2201/09827; H05K 2201/10015; H05K 2201/10204; H05K 2201/10537

(57) ABSTRACT

The present disclosure relates to a printed circuit board, including: a first insulating layer having a through-portion; a chip stack including a first chip having a rear surface opposite to a front surface on which a connection pad is disposed, and a second chip attached to the rear surface of the first chip and having a different thickness from the first chip, wherein at least a portion of the chip stack is disposed in the through-portion.; and a second insulating layer covering at least a portion of each of the first insulating layer and the chip stack and disposed in at least a portion of the through-portion.

### CROSS-REFERENCE TO RELATED APPLICATION(S)

This application claims benefit of priority to Korean Patent Application No. 10-2023-0106257 filed on Aug. 14, 2023, in the Korean Intellectual Property Office, the disclosure of which is incorporated herein by reference in its entirety.

### TECHNICAL FIELD

The present disclosure relates to a printed circuit board.

There is demand for embedding passive elements in printed circuit board to ensure power integrity of server products. However, in the case of server products, since it is basically difficult to control warpage due to a large body, there is tendency for using a thick core layer, and in this case, there is a limit to increasing a thickness of passive elements, and due to thickness inconsistency, difficulties have occurred in embedding passive elements in a core layer of a substrate. For example, when embedding a passive element that is relatively thinner than the core layer, difficulties may occur in filling empty spaces with build-up materials.

### SUMMARY

An aspect of the present disclosure is to provide printed circuit board that may easily embed a chip such as a passive element even in a case of having a thick core layer.

A solution proposed through the present disclosure is to perform an embedding process by matching a thickness of a chip stack with a thickness of the core layer as closely as possible through a chip stack in which the second chip is attached to a rear surface of a first chip.

For example, a printed circuit board according to an example embodiment may include: a first insulating layer having a through-portion; a chip stack including a first chip having a rear surface opposite to a front surface on which a connection pad is disposed, and a second chip attached to the rear surface of the first chip and having a different thickness from the first chip, wherein at least a portion of the chip stack is disposed in the through-portion; and a second insulating layer covering at least a portion of each of the first insulating layer and the chip stack and disposed in at least a portion of the through-portion.

Another solution proposed through the present disclosure is to embed first and second chips in a core layer of a substrate by attaching the first and second chips to each other in an offset manner.

For example, a printed circuit board according to another example embodiment may include: a first insulating layer having a through-portion; a first chip disposed at least partially in the through-portion and having a rear surface opposite to a front surface on which a connection pad is disposed; a second chip disposed at least partially in the through-portion and attached to the rear surface of the first chip so that an edge of the second chip is offset from the first chip on a plane; and a second insulating layer covering at least a portion of the first insulating layer and each of the first and second chips and disposed in at least a portion of the through-portion.

For example, a printed circuit board according to another example embodiment may include: a first insulating layer having a through-portion; a stack including a chip having a rear surface opposite to a front surface on which a connection pad is disposed, and a dummy element attached to the rear surface of the chip, wherein at least a portion of the stack is disposed in the through-portion; and a second insulating layer covering at least a portion of each of the first insulating layer and the stack and disposed in at least a portion of the through-portion.

As one of the various effects of the present disclosure, it may be possible to provide a printed circuit board that may easily embed a chip, such as a passive device, even in a case of having a thick core layer.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a cross-sectional view schematically illustrating an example of a printed circuit board;

FIG. 4 is a plan view schematically illustrating a cut-out surface I-I′ of the printed circuit board of FIG. 3;

FIG. 5 is a cross-sectional view schematically illustrating a modified example embodiment of the printed circuit board of FIG. 3;

FIG. 6 is process cross-sectional views schematically illustrating a manufacturing example of the printed circuit board of FIG. 3;

FIG. 7 is process cross-sectional views schematically illustrating another manufacturing example of the printed circuit board of FIG. 3;

FIG. 8 is a cross-sectional view schematically illustrating another example embodiment of a printed circuit board;

FIG. 9 is a plan view schematically illustrating a cut-out surface II-II′ of the printed circuit board of FIG. 8; and

FIG. 10 is a cross-sectional view schematically illustrating a modified example embodiment of the printed circuit board of FIG. 8.

### DETAILED DESCRIPTION

Hereinafter, the present disclosure will be described with reference to the accompanying drawings. In the drawings, the shape and size of the elements may be exaggerated or reduced for clearer description.

### Electronic Device

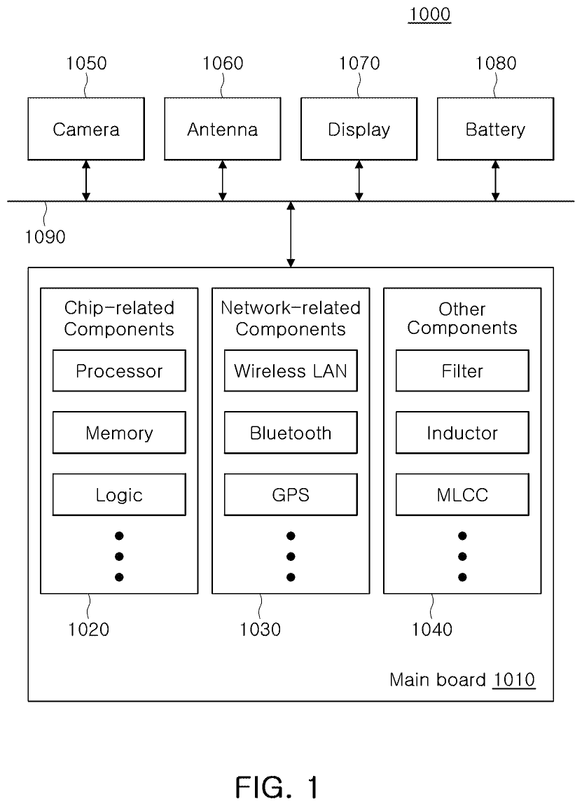

FIG. 1 is a block diagram schematically illustrating an example of an electronic device system.

Referring to FIG. 1, an electronic device 1000 accommodates a main board 1010 therein. Chip-related components 1020, network-related components 1030, and other components 1040, and the like, are physically and/or electrically connected to the main board 1010. These components are also coupled to other electronic components to be described below to form various signal lines 1090.

The chip-related components 1020 may include a memory chip such as a volatile memory (e.g., a DRAM), a non-volatile memory (e.g., a ROM), a flash memory, or the like; an application processor chip such as a central processor (e.g., a CPU), a graphics processor (e.g., a GPU), a digital signal processor, a cryptographic processor, a microprocessor, a microcontroller, or the like; and a logic chip such as an analog-to-digital (ADC) converter, an application-specific IC (ASIC), or the like. However, the chip-related components 1020 are not limited thereto, and may also include other types of chip-related electronic components. Furthermore, the chip-related components 1020 may be coupled to each other. The chip-related component 1020 may have the form of a package including the above-described chip or electronic component.

The network-related components 1030 may include wireless fidelity (Wi-Fi) (such as IEEE 802.11 family), worldwide interoperability for microwave access (WiMAX) (such as IEEE 802.16 family), IEEE 802.20, long term evolution (LTE), evolution data only (Ev-DO), HSPA+, HSDPA+, HSUPA+, EDGE, GSM, GPS, GPRS, CDMA, TDMA, DECT, Bluetooth, 3G, 4G, and 5G protocols, and any other wireless and wired standards or protocols specified thereafter. However, the network-related components 1030 are not limited thereto, and may also include any of a number of other wireless or wired standards or protocols. Furthermore, the network-related components 1030 may be coupled to the chip-related components 1020.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components are not limited thereto, and may also include passive components in the form of chip components used for various other purposes. In addition, other components 1040 may be coupled to each other, together with the chip-related components 1020 and/or the network-related components 1030.

Depending on a type of electronic device 1000, the electronic device 1000 may include other electronic components that may or may not be physically and/or electrically connected to main board 1010. These other electronic components may include, for example, a camera module 1050, an antenna module 1060, a display 1070, and a battery 1080. However, these other electronic components are not limited thereto, but may also include an audio codec, a video codec, a power amplifier, a compass, an accelerometer, a gyroscope, a speaker, a mass storage device (e.g., a hard disk drive), a compact disk (CD), a digital versatile disk (DVD), or the like. In addition thereto, other electronic components used for various purposes depending on a type of electronic device 1000 may be included.

The electronic device 1000 may be a smartphone, a personal digital assistant, a digital video camera, a digital still camera, a network system, a computer, a monitor, a tablet PC, a laptop PC, a netbook PC, a television, a video game machine, a smartwatch, an automotive component. However, the electronic device 1000 is not limited thereto, and may be any other electronic device that processes data in addition thereto.

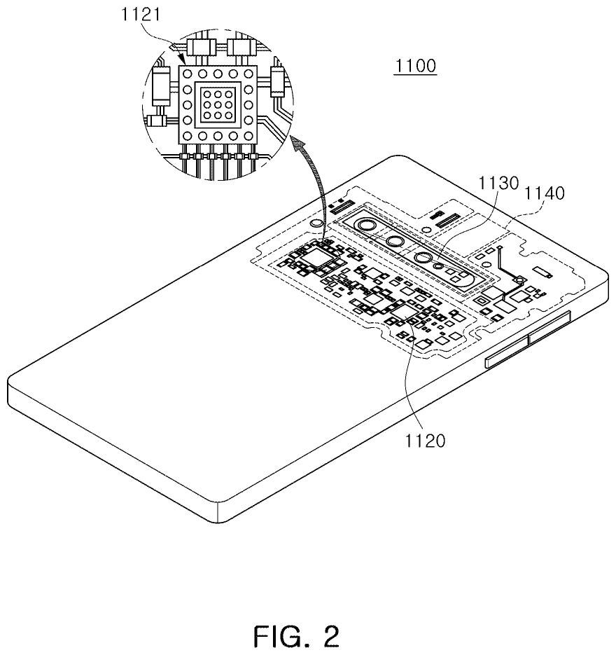

FIG. 2 is a perspective view schematically illustrating an example of an electronic device.

Referring to FIG. 2, an electronic device may be, for example, a smartphone 1100. A mother board 1110 may be accommodated in the smartphone 1100, and various components 1120 may be physically and/or electrically connected to the mother board 1110. Furthermore, other components that may or may not be physically and/or electrically connected to the mother board 1110, such as a camera module 1130 and/or a speaker 1140, may be accommodated in the smartphone 1100. Some of the components 1120 may be the chip-related components described above, for example, the component package 1121, but the present disclosure is not limited thereto. The component package 1121 may have the form of a printed circuit board in which an electronic component including an active component and/or a passive component is mounted on a surface. Alternatively, the component package 1121 may have the form of a printed circuit board in which an active component and/or a passive component are embedded. On the other hand, the electronic device is not necessarily limited to the smartphone 1100, and may be other electronic devices as described above.

### Printed Circuit Board

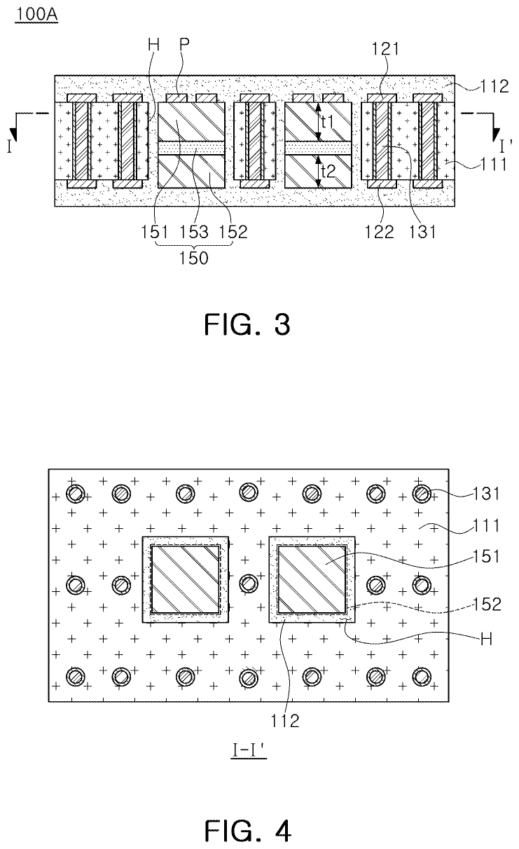

FIG. 3 is a cross-sectional view schematically illustrating an example of a printed circuit board.

FIG. 4 is a plan view schematically illustrating a cut-out surface I-I′ of the printed circuit board of FIG. 3.

Referring to the drawings, a printed circuit board 100A according to an example embodiment may include a first insulating layer 111 having a through-portion H, a chip stack 150 including a first chip 151 having a rear surface opposite to a front surface on which a connection pad P is disposed, and a second chip 152 attached to the rear surface of the first chip 151 through an adhesive 153, at least a portion of the chip stack 150 being disposed in the through-portion H, a second insulating layer 112 covering at least a portion of each of the first insulating layer 111 and the chip stack 150 and filling at least a portion of the through-portion H, first and second wiring layers 121 and 122 respectively disposed on an upper surface and a lower surface of the first insulating layer 111, and a first via layer 131 penetrating through the first insulating layer 111 and connecting at least a portion of each of the first and second wiring layers 121 and 122 to each other. A thickness t2 of the second chip 152 may be different from a thickness t1 of the first chip 151. The through-portion H and the chip stack 150 may be provided in plural form, and at least a portion of the plurality of chip stacks 150 may be disposed in the plurality of through-portions H.

In this manner, in the printed circuit board 100A according to an example embodiment, the chip stack 150 in which the first and second chips 151 and 152 are stacked vertically through the adhesive 153 may be disposed in the through-portion H of the first insulating layer 111. Accordingly, even when the thickness of the first insulating layer 111 is thick, for example, even when the thickness of the first insulating layer 111 is 1.2 mm or more, a thickness of the chip stack 150 may be matched thereto as closely as possible. Furthermore, even when the first insulating layer 111 is comprised of one layer rather than multiple layers, the thickness of the chip stack 150 may be increased as desired, such as 1.2 mm or more, and as a result, warpage stability may be further improved. Furthermore, since the thickness t2 of the second chip 152 may be adjusted to a thickness different from the thickness t1 of the first chip 151, it may be easier to control the chip stack 150 to a desired thickness. Accordingly, when filling the through-portion H with the second insulating layer 112, filling may be more easily performed. Additionally, the process may be simplified, which may have the effect of reducing investment costs.

Meanwhile, the first chip 151 may include a passive element, and more preferably, a silicon capacitor. When the first chip 151 includes the silicon capacitor, power integrity may be secured more effectively when the printed circuit board 100A is applied to a server product. In this case, when the first chip 151 includes a silicon capacitor, for warpage stability, the second chip 152 may also include a silicon body, and for example, the second chip 152 may include a silicon dummy. For example, each of the first and second chips 151 and 152 may include a silicon die as a base, and the adhesive 153 connecting the first and second chips 151 and 152 may be a die attach film (DAF). If necessary, the second chip 152, like the first chip 151, may include a silicon capacitor with a connection pad disposed on a front surface thereof. Silicon capacitors may be embedded in a form in which rear surfaces thereof are attached to each other through the adhesive 153 and the connection pads face in opposite directions.

Hereinafter, components of the printed circuit board 100A according to an example embodiment will be described in more detail with reference to the drawings.

Each of the first and second insulating layers 111 and 112 may include an insulating material. The insulating material may include a thermosetting resin such as an epoxy resin, a thermoplastic resin such as polyimide, or materials including an inorganic filler, an organic filler, and/or a glass fiber (Glass Fiber, Glass Cloth or Glass Fabric) along with resins. For example, the insulating material may be a non-photosensitive insulating material such as Copper Clad Laminate (CCL), an Ajinomoto Build-up Film (ABF), or Prepreg (PPG), but the present disclosure is not limited thereto. In addition, other polymer materials may be used. Additionally, the insulating material may be a photosensitive insulating material such as Photo Imageable Dielectric (PID). As a non-limiting example, the first insulating layer 111 may include CCL, and the second insulating layer 112 may include ABF or PPG. The first insulating layer 111 may be a core layer, and the second insulating layer 112 may be a build-up layer. The first insulating layer 111 may be one layer, and the second insulating layer 112 may include a plurality of layers.

The first and second wiring layers 121 and 122 may each include a metallic material. The metallic material may include copper (Cu), aluminum (Al), silver (Ag), tin (Sn), gold (Au), nickel (Ni), lead (Pb), titanium (Ti), and/or alloys thereof. The metallic material may include, preferably, copper (Cu), but the present disclosure is not limited thereto. Each of the first and second wiring layers 121 and 122 may perform various functions depending on the design. For example, the first and second wiring layers 121 and 122 may include a signal pattern, a power pattern, a ground pattern. Each of these patterns may have various forms such as a line, a plane, and a pad. Each of the first and second wiring layers 121 and 122 may include an electroless plating layer (or chemical copper) and an electrolytic plating layer (or electrolytic copper), respectively. Alternatively, the first and second wiring layers 121 and 122 may include a metal foil (or copper foil) and an electrolytic plating layer (or electrolytic copper). Alternatively, the first and second wiring layers 121 and 122 may include a metal foil (or copper foil), an electroless plating layer (or chemical copper), and an electrolytic plating layer (or electrolytic copper). The first and second wiring layers 121 and 122 may include a sputtering layer instead of an electroless plating layer (or chemical copper), and may include both the sputtering layer and the electroless plating layer (or chemical copper), if necessary.

The first via layer 131 may include a metallic material. The metallic material may include copper (Cu), aluminum (Al), silver (Ag), tin (Sn), gold (Au), nickel (Ni), lead (Pb), titanium (Ti), and/or alloys thereof. The metallic material may include, preferably, copper (Cu), but the present disclosure is not limited thereto. The first via layer 131 may include a through-via. The through-via may include a Plated Through-Hole (PTH) formed conformally by plating the above-described metallic material on a wall surface of a through-hole penetrating through the first insulating layer 111 and filled with an insulating material. The through-via of the first via layer 131 may perform various functions depending on the design of the corresponding layer. For example, the first via layer 131 may include a ground via, a power via, and a signal via. The first via layer 131 may include an electroless plating layer (or chemical copper) and an electrolytic plating layer (or electrical copper), but the present disclosure is not limited thereto. The first via layer 131 may have a sputtering layer formed therein instead of the electroless plating layer, and may include both the sputtering layer and the electroless plating layer.

Each of the first and second chips 151 and 152 may each include a silicon die. The silicon die may include an integrated circuit therein. However, the present disclosure is not limited thereto and the silicon die may simply be a dummy die. The silicon die may be formed based on an active wafer, in which case, silicon (Si) and the like may be used as a base material forming each body. The connection pad P may include a conductive material such as aluminum (Al) or copper (Cu). A surface on which the connection pad P is disposed may be a front surface or an active surface, and an opposite side thereof may be a rear surface or an inactive surface. The first chip 151 may include a silicon capacitor, and the second chip 152 may include a silicon dummy as a dummy element, but if necessary, the second chip 152 may also include a silicon capacitor. In a case that the second chip 152 is a dummy element, the second chip 152 may electrically insulated from the first and second wiring layers 121 and 122 and the first via layer 131, although the present disclosure is not limited thereto.

The adhesive 153 may be disposed between the first and second chips 151 and 152 to connect the first and second chips 151 and 152 to each other. For example, the second chip 152 may be attached to the rear surface of the first chip 151 through the adhesive 153. The adhesive 153 may include an adhesive component such as epoxy. The adhesive 153 may have a film type and may include, for example, a die attach film (DAF), but the present disclosure is not limited thereto. The adhesive 153 may be thinner than the first and second chips 151 and 152, respectively.

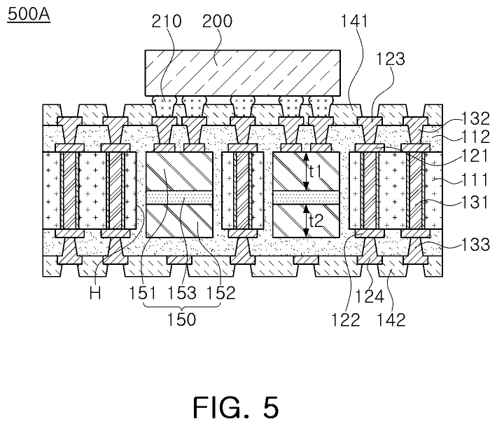

FIG. 5 is a cross-sectional view schematically illustrating a modified example embodiment of the printed circuit board of FIG. 3.

Referring to FIG. 5, a printed circuit board 500A according to a modified example embodiment may further include third and fourth wiring layers 123 and 124 respectively disposed on an upper surface and a lower surface of the second insulating layer 112, a second via layer 132 penetrating through a portion of an upper side of the second insulating layer 112 and connecting at least a portion of each of the first and third wiring layers 121 and 123 and at least a portion of each of the first wiring layer 121 and the connection pad P to each other, a third via layer 133 penetrating through a portion of a lower side of the second insulating layer 112 and connecting at least a portion of each of the second and fourth wiring layers 122 and 124 to each other, first and second resist layers 141 and 142 respectively disposed on an upper surface and a lower surface of the second insulating layer 112 and having an opening exposing at least a portion of each of the third and fourth wiring layers 123 and 124, respectively, and a semiconductor chip 200 disposed on the first resist layer 141 and connected to an exposed portion of the third wiring layer 123 through a connecting member 210, in the printed circuit board 100A according to the example embodiment.

In this manner, the printed circuit board 500A according to the modified example embodiment may include the printed circuit board 100A according to the example embodiment as a package substrate with the chip stack 150 embedded therein, and may have a form of a semiconductor package with a semiconductor chip 200 mounted thereon.

Hereinafter, the components of the printed circuit board 500A according to the modified example embodiment will be described in more detail with reference to the drawings.

Each of the third and fourth wiring layers 123 and 124 may include a metallic material. The metallic material may include copper (Cu), aluminum (Al), silver (Ag), tin (Sn), gold (Au), nickel (Ni), lead (Pb), titanium (Ti), and/or alloys thereof. The metallic material may include, preferably, copper (Cu), but the present disclosure is not limited thereto. Each of the third and fourth wiring layers 123 and 124 may perform various functions depending on the design. For example, the third and fourth wiring layers 123 and 124 may include a signal pattern, a power pattern, and a ground pattern. Each of these patterns may have various forms such as a line, a plane, and a pad. The third and fourth wiring layers 123 and 124 may include an electroless plating layer (or chemical copper) and an electrolytic plating layer (or electrolytic copper), respectively. Alternatively, the third and fourth wiring layers 123 and 124 may include a metal foil (or copper foil) and an electrolytic plating layer (or electrolytic copper). Alternatively, the third and fourth wiring layers 123 and 124 may include a metal foil (or copper foil), an electroless plating layer (or chemical copper), and an electrolytic plating layer (or electrolytic copper). The third and fourth wiring layers 123 and 124 may include a sputtering layer may instead of an electroless plating layer (or chemical copper), and may include both the sputtering layer and the electroless plating layer (or chemical copper), if necessary.

Each of the second and third via layers 132 and 133 may include a metallic material. The metallic material may include copper (Cu), aluminum (Al), silver (Ag), tin (Sn), gold (Au), nickel (Ni), lead (Pb), titanium (Ti), and/or alloys thereof. The metallic material 1 may include, preferably, copper (Cu), but the present disclosure is not limited thereto. Each of the second and third via layers 132 and 133 may include a micro via. The micro via may be a filled via filling a via hole or may be a conformal via disposed along a wall surface of the via hole. The micro via may be arranged as a stacked type and/or a staggered type. The micro via of the second and third via layers 132 and 133 may perform various functions depending on the design of the corresponding layer. For example, the second and third via layers 132 and 133 may include a ground via, a power via, and a signal via. Each of the second and third via layers 132 and 133 may include an electroless plating layer (or chemical copper) and an electrolytic plating layer (or electrolytic copper), but the present disclosure is not The second and third via layers 132 and limited thereto. 133 may have a sputtering layer formed therein instead of an electroless plating layer, and may include both the sputtering layer and the electroless plating layer. The second and third via layers 132 and 133 may have a shape tapered in opposite directions. In a case that the second chip 152 is a dummy element, the second chip 152 may electrically insulated from the first to fourth wiring layers 121 to 124 and the first to third via layers 131 to 133, although the present disclosure is not limited thereto.

Each of the first and second resist layers 141 and 142 may include a liquid or film-type solder resist, but the present disclosure is not limited thereto, and the first and second resist layers 141 and 142 may include other types of insulating materials such as ABF. The first and second resist layers 141 and 142 may have an opening exposing at least a portion of the third and fourth wiring layers 123 and 124, respectively, and may have a surface treatment layer formed on an exposed pattern as needed.

The semiconductor chip 200 may include an integrated circuit (IC) die in which several hundreds to serval millions of elements are integrated into one chip. In this case, the integrated circuit may be, for example, a logic chip such as a central processor (e.g., CPU), a graphics processor (e.g., GPU), a field programmable gate array (FPGA), a digital signal processor, a cryptographic processor, a microprocessor, a microcontroller, an application processor (e.g., AP), an analog-to-digital converter, and an application-specific IC (ASIC), but the present disclosure is not limited thereto, and the integrated circuit may be a memory chip such as a volatile memory (e.g., DRAM), a non-volatile memory (e.g., ROM), a flash memory, and a High Bandwidth Memory (HBM), or other types such as Power Management IC (PMIC).

The semiconductor chip 200 may be formed based on an active wafer, in which case, silicon (Si), germanium (Ge), and gallium arsenide (GaAs) may be used as base materials forming each body. Various circuits may be formed in the body. A connection pad may be formed on the body, and the connection pad may include a conductive material such as aluminum (Al) or copper (Cu). The semiconductor chip 200 may be a bare die, and in this case, metal bumps may be disposed on the connection pad. The semiconductor chip 200 may be a packaged die, in which case a redistribution layer may be additionally formed on the connection pad, and metal bumps may be disposed on the redistribution layer.

The connecting member 210 may be formed of a low melting point metal, for example, a solder such as tin (Sn)—aluminum (Al)—copper (Cu), but this is only an example and a material thereof is not specifically limited thereto. The connecting member 210 may be formed in multiple layers or a single layer. When the connection member 210 is formed in multiple layers, the connection member 210 may include a copper pillar and a solder, and when the connection member 210 is formed in a single layer, the connection member 210 may include a tin-silver solder or copper, but the present disclosure is not limited thereto. The connecting members 210 may be provided in plural form.

Other contents are substantially the same as those described for the printed circuit board 100A according to the above-described example embodiment, and therefore overlapping descriptions thereof will be omitted.

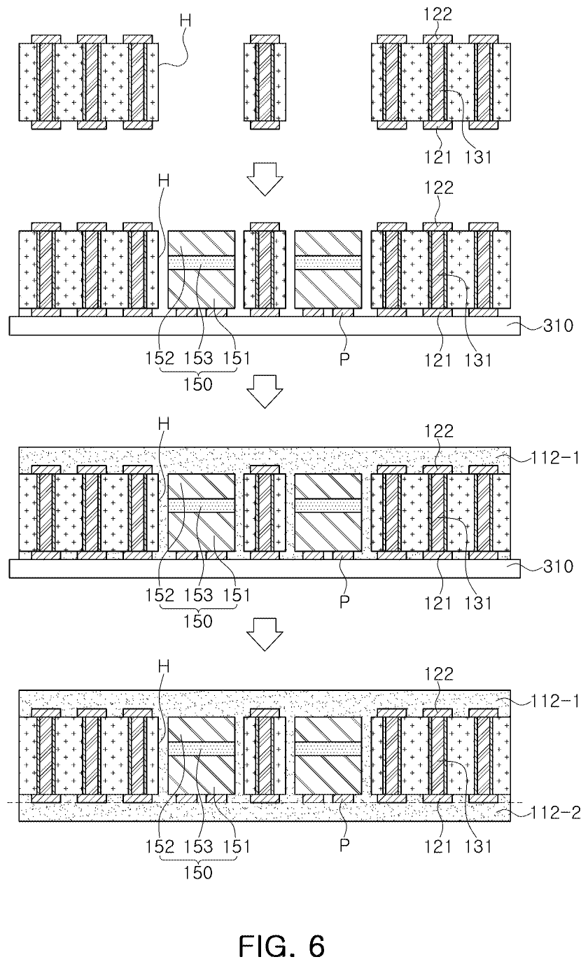

FIG. 6 is process cross-sectional views schematically illustrating a manufacturing example of the printed circuit board of FIG. 3.

Referring to FIG. 6, first, a first insulating layer 111 is prepared using CCL, and the like, and a through-portion H, first and second wiring layers 121 and 122 and a first via layer 131 are formed in the first insulating layer 111. The through-portion H may be formed using mechanical drilling, laser drilling, blast processing, and the like. A via hole for the first via layer 131 may also be formed using a mechanical drill, laser drill, and the like. The first and second wiring layers 121 and 122 and the first via layer 131 may be formed through a circuit formation process such as Additive Process (AP), Semi AP (SAP), Modified SAP (MSAP), and Tenting (TT). When forming the first via layer 131, a plugging process filling an interior of the through-via with an insulating material may be included. Next, a tape 310 is attached to a lower side of the first insulating layer 111. The tape 310 may be attached to the first wiring layer 121. The tape 310 may block a lower portion of the through-portion (H). Then, a previously formed chip stack 150 is disposed in the through-portion H by connecting the first and second chips 151 and 152 with the adhesive 153 according to a thickness of the first insulating layer 111. For example, the chip stack 150 may be disposed so that a front surface of the first chip 151 on which the connection pad P is disposed is attached to the tape 310. Next, a second-first insulating layer 112-1 burying the first insulating layer 111, the first and second wiring layers 121 and 122 and the chip stack 150 and filling the through-portion H is formed on the tape 310. The second-first insulating layer 112-1 may be formed in a lamination process while attached to a film such as PolyEthylene Terephthalate (PET). Next, the tape 310 is removed. Then, a second-second insulating layer 112-2 is formed in a region from which the tape 310 was removed, for example, below the second-first insulating layer 112-1. The second-second insulating layer 112-2 may also be formed in a lamination process while attached to a film such as PET. The second-first and second-second insulating layers 112-1 and 112-2 may be integrated to the extent that boundaries thereof are not distinguishable from each other after curing and become the second insulating layer 112.

The printed circuit board 100A according to the above-described example embodiment may be manufactured in a series of processes, and other overlapping descriptions thereof will be omitted. Meanwhile, in the series of processes, a process is described to proceed in a vertically inverted form, as compared to the printed circuit board 100A according to the above-described example embodiment, and it is obvious that the printed circuit board 100A according to the above-described example embodiment may be manufactured through vertical inversion after the process is completed.

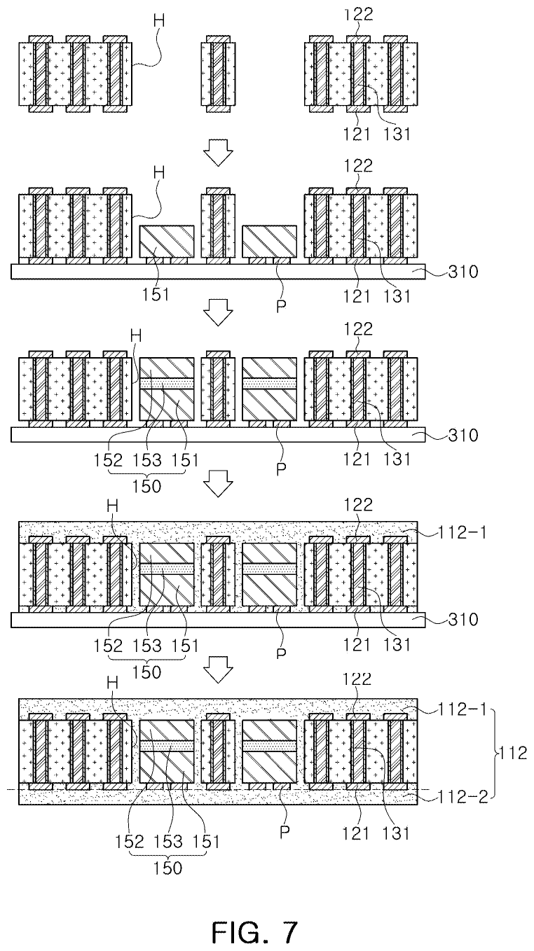

FIG. 7 is process cross-sectional views schematically illustrating another manufacturing example of the printed circuit board of FIG. 3.

Referring to FIG. 7, first, a first insulating layer 111 is prepared using CCL, and the like, and a through-portion H, first and second wiring layers 121 and 122, and a first via layer 131 are formed in a first insulating layer 111. The through-portion H may be formed using mechanical drilling, laser drilling, blast processing, and the like. A via hole for the first via layer 131 may also be formed using a mechanical drill, laser drill, and the like. The first and second wiring layers 121 and 122 and the first via layer 131 may be formed in a circuit formation process such as an Additive Process (AP), a Semi AP (SAP), a Modified SAP (MSAP), and Tenting (TT). When forming the first via layer 131, a plugging process of filling an interior of a through-via with an insulating material may be included. Next, a tape 310 is attached to a lower side of the first insulating layer 111. The tape 310 may be attached to the first wiring layer 121. The tape 310 may block a lower portion of the through-portion H. Then, a first chip 151 is disposed in the through-portion H. For example, the first chip 151 may be disposed so that a front surface on which the connection pad P is disposed is attached to the tape 310. Next, a second chip 152 is attached to a rear surface of the first chip 151 in the through-portion H using an adhesive 153 to form a chip stack 150. In this case, the second chip 152 may have a thickness set so that a thickness of the chip stack 150 approximately matches a thickness of the first insulating layer 111. Next, a second-first insulating layer 112-1 burying the first insulating layer 111, the first and second wiring layers 121 and 122 and the chip stack 150 and filling the through-portion H is on the tape 310. The second-first insulating layer 112-1 may be formed in a lamination process while attached to a film such as PET. Next, the tape 310 is removed. Then, a second-second insulating layer 112-2 is formed in a region from which the tape 310 was removed, for example, below the second-first insulating layer 112-1. The second-second insulating layer 112-2 may also be formed in a lamination process while attached to a film such as PET.

The second-first and second-second insulating layers 112-1 and 112-2 may be integrated to the extent that boundaries thereof are not distinguishable from each other after curing.

A printed circuit board 100A according to the above-described example embodiment may be manufactured in a series of processes, and other overlapping descriptions thereof are omitted. Meanwhile, in the series of processes, a process is described to proceed in a vertically inverted form, as compared to the printed circuit board 100A according to the above-described example embodiment, and it is obvious that the printed circuit board 100A according to the above-described example embodiment may be manufactured through vertical inversion after the process is completed.

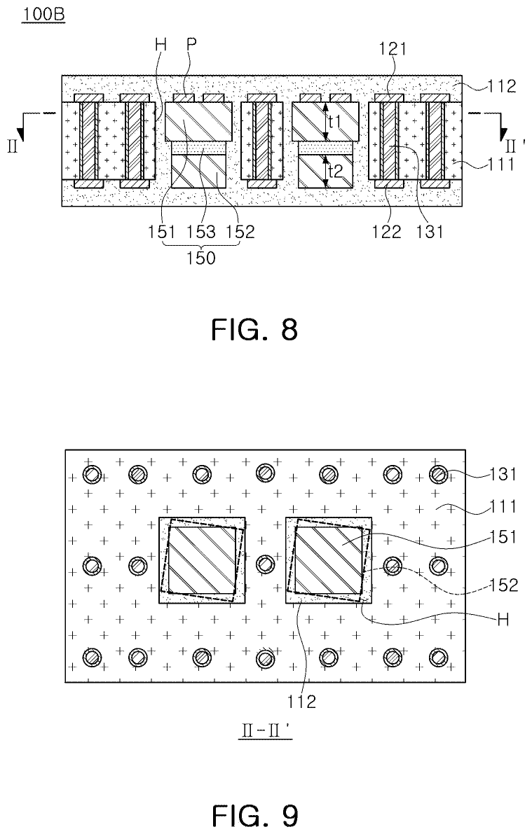

FIG. 8 is a cross-sectional view schematically illustrating another example embodiment of a printed circuit board.

FIG. 9 is a plan view schematically illustrating a cut-out surface II-II′ of the printed circuit board of FIG. 8.

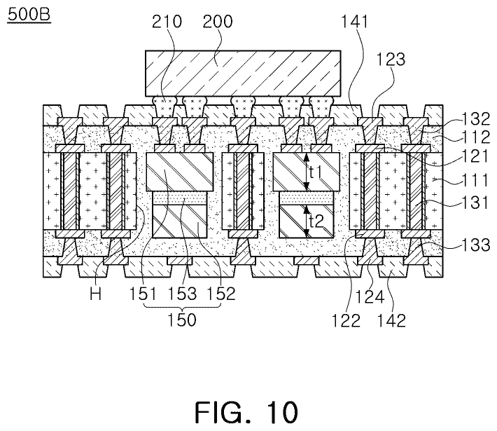

FIG. 10 is a cross-sectional view schematically illustrating a modified example embodiment of the printed circuit board of FIG. 8.

Referring to the drawings, a printed circuit board 100B according to another example embodiment and a printed circuit board 500B according to a modified example embodiment may be attached to a rear surface of a first chip 151 in a state in which a second chip 152 is rotated to be offset from the first chip 151 when viewed from above, in the printed circuit board 100A according to the example embodiment and the printed circuit board 500A according to the modified example embodiment, as described above. For example, an edge of the second chip 152 may be offset from an edge of the first chip 151 on a plane. For example, a side surface of the second chip 152 may have a step portion from a side surface of the first chip 151 in a cross-section. Accordingly, the second chip 152 may be more easily attached to the first chip 151, and it may also be easier to fill the through-portion H with the second insulating layer 112. Additionally, the process may be simplified, which may have the effect of reducing investment costs.

Other contents are substantially the same as those described in the printed circuit board 100A according to the example embodiment and the printed circuit board 500A according to the modified example embodiment, as described above, and therefore overlapping descriptions thereof will be omitted. In addition, the above-described content may be applied substantially in the same manner to a manufacturing process, and therefore, overlapping description thereof will also be omitted.

In the present disclosure, the expression ‘covering’ may include a case of covering at least a portion as well as a case of covering the whole, and may also include a case of covering not only directly but also indirectly. Furthermore, the expression ‘filling’ may include not only a case of completely filling but also a case of approximately filling, and may include, for example, a case in which some pores or voids exist.

In the present disclosure, the meaning on the cross-section may refer to a cross-sectional shape when an object is cut vertically, or a cross-sectional shape when the object is viewed in a side-view. Furthermore, the meaning on a plane may refer to a planar shape when the object is horizontally cut, or a planar shape when the object is viewed in a top-view or a bottom-view.

In the present disclosure, a thickness, a width, a length, a depth, and the like may be measured with a scanning microscope or an optical microscope based on a cross-section in which a printed circuit board is polished or cut. The cut cross-section may be a vertical cross-section or a horizontal cross-section, and each numerical value thereof may be measured based on a required cut cross-section. When the numerical value is not constant, the numerical value may be determined as an average value of values measured at any five points. A width of an upper end and/or a lower end of a via or a pattern groove may be measured on a cross-section obtained by cutting a central axis of a via in a thickness direction of a substrate. A depth of the via or the pattern groove may be measured as a distance from an upper end to a lower end of each object on a cross-section obtained by cutting a central axis of each object in the thickness direction of the substrate.

In the present disclosure, a lower side, a lower portion, and a lower surface are used to refer to a downward direction with respect to a cross-section of a drawing, and an upper side, an upper portion, and an upper surface are used to refer to an opposite direction thereof. Furthermore, a side portion, a side surface, and the like, are used to denote directions, perpendicular to upper and lower surfaces. However, this defines the direction for convenience of explanation, and the scope of the rights of the claims is not particularly limited by the description of such a direction, and the concept of upper and lower portions may be changed at any time.

In the present disclosure, a meaning of being connected is a concept including not only directly connected but also indirectly connected through an adhesive layer or the like. Furthermore, a meaning of electrically connected is a concept including both physically connected and not connected. In addition, expressions such as first and second are used to distinguish one component from another, and do not limit the order and/or importance of the components. In some cases, a first component may be referred to as a second component without departing from the scope of rights, or similarly, the second component may be referred to as the first component.

The expression ‘example embodiment used in the present disclosure’ does not mean the same embodiment, and is provided to explain different unique characteristics. However, the example embodiments presented above do not preclude being implemented in combination with features of other example embodiments. For example, even if matters described in a particular example embodiment are not described in other example embodiments, they may be understood as explanations related to other example embodiments unless there is an explanation contrary to or contradictory to matters in other example embodiments.

The terms used in the present disclosure are used only to describe an example embodiment and are not intended to limit the present disclosure. In this case, singular expressions include plural expressions unless they are clearly meant differently in the context.

What is claimed is:

1. A printed circuit board, comprising:
a first insulating layer having a through-portion;
a chip stack including a first chip having a rear surface opposite to a front surface on which a connection pad is disposed, and a second chip attached to the rear surface of the first chip and having a different thickness from the first chip, wherein at least a portion of the chip stack is disposed in the through-portion; and
a second insulating layer covering at least a portion of each of the first insulating layer and the chip stack and disposed in at least a portion of the through-portion.

2. The printed circuit board according to claim 1, wherein the first chip includes a silicon capacitor.

3. The printed circuit board according to claim 2, wherein the second chip includes a silicon dummy.

4. The printed circuit board according to claim 1, wherein the chip stack further includes an adhesive disposed between the first and second chips.

5. The printed circuit board according to claim 4, wherein the adhesive includes a die attach film.

6. The printed circuit board according to claim 1, wherein the first insulating layer is a layer having a thickness of 1.2 mm or more.

7. The printed circuit board according to claim 1, further comprising:
first and second wiring layers respectively disposed on an upper surface and a lower surface of the first insulating layer; and
a first via layer penetrating through the first insulating layer and connecting at least a portion of each of the first and second wiring layers to each other.

8. The printed circuit board according to claim 7, further comprising:
third and fourth wiring layers respectively disposed on an upper surface and a lower surface of the second insulating layer;
a second via layer penetrating through a portion of an upper side of the second insulating layer, and connecting at least a portion of each of the first and third wiring layers and at least a portion of each of the first wiring layer and the connection pad to each other; and
a third via layer penetrating through a portion of a lower side of the second insulating layer, and connecting at least a portion of each of the second and fourth wiring layers to each other.

9. The printed circuit board according to claim 8, further comprising:
first and second resist layers respectively disposed on an upper surface and a lower surface of the second insulating layer, and having an opening exposing at least a portion of each of the third and fourth wiring layers.

10. The printed circuit board according to claim 9, further comprising:
a semiconductor chip disposed on the first resist layer and connected to an exposed portion of the third wiring layer.

11. The printed circuit board according to claim 1, wherein each of the through-portion and the chip stack is provided in plural form, and
each of the plurality of chip stacks is at least partially disposed in the plurality of through-portions.

12. A printed circuit board, comprising:
a first insulating layer having a through-portion;
a first chip disposed at least partially in the through-portion and having a rear surface opposite to a front surface on which a connection pad is disposed;
a second chip disposed at least partially in the through-portion and attached to the rear surface of the first chip so that an edge of the second chip is offset from the first chip on a plane; and
a second insulating layer covering at least a portion of the first insulating layer and each of the first and second chips and disposed in at least a portion of the through-portion.

13. The printed circuit board according to claim 12, wherein a side surface of the second chip has a step portion from a side surface of the first chip in a cross-section.

14. The printed circuit board according to claim 12, further comprising:
an adhesive disposed between the first and second chips and attaching the second chip to the rear surface of the first chip.

15. The printed circuit board according to claim 14, wherein each of the first and second chips includes a silicon die, and
the adhesive includes a die attach film.

16. The printed circuit board according to claim 12, further comprising:
first and second wiring layers disposed above and below the first insulating layer, respectively; and
a first via layer disposed at least partially in the first insulating layer and connecting at least a portion of each of the first and second wiring layers to each other.

17. The printed circuit board according to claim 16, further comprising:
third and fourth wiring layers disposed above and below the second insulating layer, respectively;
a second via layer disposed at least partially in an upper side of the second insulating layer, and connecting at least a portion of each of the first and third wiring layers and at least a portion of each of the first wiring layer and the connection pad to each other; and
a third via layer disposed at least partially in a lower side of the second insulating layer, and connecting at least a portion of each of the second and fourth wiring layers to each other.

18. A printed circuit board, comprising:
a first insulating layer having a through-portion;
a stack including a chip having a rear surface opposite to a front surface on which a connection pad is disposed, and a dummy element attached to the rear surface of the chip, wherein at least a portion of the stack is disposed in the through-portion; and
a second insulating layer covering at least a portion of each of the first insulating layer and the stack and disposed in at least a portion of the through-portion.

19. The printed circuit board according to claim 18, further comprising:
first and second wiring layers respectively disposed on an upper surface and a lower surface of the first insulating layer;
a first via layer penetrating through the first insulating layer and connecting at least a portion of each of the first and second wiring layers to each other;
third and fourth wiring layers respectively disposed on an upper surface and a lower surface of the second insulating layer;
a second via layer penetrating through a portion of an upper side of the second insulating layer, and connecting at least a portion of each of the first and third wiring layers and at least a portion of each of the first wiring layer and the connection pad to each other; and
a third via layer penetrating through a portion of a lower side of the second insulating layer, and connecting at least a portion of each of the second and fourth wiring layers to each other.

20. The printed circuit board according to claim 19, wherein the dummy element is electrically insulated from the first to fourth wiring layers and the first to third via layers.
